(19) United States
(12) Patent Application Publication
(10) Pub. No.: US 2025/0344372 A1
(43) Pub. Date: Nov. 6, 2025

(54) MEMORY DEVICE INCLUDING WORD LINE STRUCTURE HAVING LOWER AND UPPER GATE ELECTRODE LAYERS AND METHOD FOR PREPARING THE SAME

(71) Applicant: NANYA TECHNOLOGY CORPORATION, NEW TAIPEI CITY (TW)

(72) Inventor: YING-CHENG CHUANG, NEW TAIPEI CITY (TW)

(21) Appl. No.: 18/655,444

(22) Filed: May 6, 2024

(51) Int. Cl. H10B 12/00

(52) U.S. Cl. CPC H10B 12/34; H10B 12/053; H10B 12/315

(57) ABSTRACT

A memory device includes a word line structure disposed in a semiconductor substrate. The word line structure includes a lower gate electrode layer, an upper gate electrode layer, a pair of spacers disposed on opposite sides of the upper gate electrode layer, and a gate dielectric layer surrounding the lower gate electrode layer and the pair of spacers. The lower gate electrode layer and the upper gate electrode layer have different work functions. The memory device also includes a first source/drain region and a second source/drain region disposed in the semiconductor substrate and at opposite sides of the word line structure. The memory device further includes a bit line structure disposed over and electrically connected to the first source/drain region, and a capacitor disposed over and electrically connected to the second source/drain region.

### TECHNICAL FIELD

The present disclosure relates to a memory device and a method for preparing the same, and more particularly, to a memory device including a word line structure having a lower gate electrode layer and an upper electrode layer and a method for preparing the same.

### DISCUSSION OF THE BACKGROUND

Due to structural simplicity, dynamic random access memories (DRAMs) can provide more memory cells per unit chip area than other types of memories, such as static random access memories (SRAMs). A DRAM is constituted by a plurality of DRAM cells, each of which includes a capacitor for storing information and a transistor coupled to the capacitor for regulating when the capacitor is charged or discharged. During a read operation, a word line (WL) is asserted, turning on the transistor. The enabled transistor allows the voltage across the capacitor to be read by a sense amplifier through a bit line (BL). During a write operation, the data to be written is provided on the BL while the WL is asserted.

To satisfy the demand for greater memory storage, the dimensions of the DRAM memory cells have continuously shrunk so that the packing densities of these DRAMs have increased considerably. However, the manufacturing and integration of memory devices involve many complicated steps and operations. Integration in memory devices becomes increasingly complicated. An increase in complexity of manufacturing and integration of the memory device may cause deficiencies, such as gate induced drain leakage (GIDL). Accordingly, there is a continuous need to improve the structure and the manufacturing process of memory devices so that the deficiencies can be addressed, and the performance can be enhanced.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

In one embodiment of the present disclosure, a memory device is provided. The memory device includes a word line structure disposed in a semiconductor substrate. The word line structure includes a lower gate electrode layer, and an upper gate electrode layer disposed over the lower gate electrode layer. A work function of the lower gate electrode layer is different from a work function of the upper gate electrode layer. In addition, the word line structure includes a pair of spacers disposed on opposite sides of the upper gate electrode layer, and a gate dielectric layer surrounding the lower gate electrode layer and the pair of spacers. The memory device also includes a first source/drain region and a second source/drain region disposed in the semiconductor substrate and at opposite sides of the word line structure. The memory device further includes a bit line structure disposed over and electrically connected to the first source/drain region, and a capacitor disposed over and electrically connected to the second source/drain region.

In an embodiment, the work function of the lower gate electrode layer is higher than the work function of the upper gate electrode layer. In an embodiment, the lower gate electrode layer includes titanium nitride (TiN), and the upper gate electrode layer includes polysilicon. In an embodiment, the lower gate electrode layer is in direct contact with the upper gate electrode layer. In an embodiment, the gate dielectric layer has a lower portion surrounding the lower gate electrode layer and an upper portion, and a thickness of the lower portion of the gate dielectric layer is greater than a thickness of the upper portion of the gate dielectric layer. In an embodiment,

In an embodiment, the upper gate electrode layer is separated from the gate dielectric layer by the pair of spacers. In an embodiment, the lower gate electrode layer is in direct contact with the pair of spacers. In an embodiment, the memory device further includes a dielectric cap layer disposed over the semiconductor substrate, wherein a portion of the dielectric cap layer extends into the semiconductor substrate to cover the word line structure. In an embodiment, the dielectric cap layer is in direct contact with the upper gate electrode layer. In an embodiment, the dielectric cap layer is in direct contact with the pair of spacers.

In an embodiment, the memory device further includes a lining layer disposed between the gate dielectric layer and the dielectric cap layer. In an embodiment, the lining layer is in direct contact with the pair of spacers. In an embodiment, the upper gate electrode layer and the pair of spacers are separated from the dielectric cap layer by the lining layer. In an embodiment, the lining layer extends over the semiconductor substrate, and a top surface of the gate dielectric layer is covered by the lining layer. In an embodiment, the memory device further includes a bit line contact disposed between the first source/drain region and the bit line structure, wherein the bit line contact is in direct contact with the lining layer. In an embodiment, the memory device further includes a mask layer disposed between the capacitor and the second source/drain region of the semiconductor substrate, wherein the mask layer is in direct contact with the lining layer. In an embodiment, the memory device further includes a capacitor contact disposed between and electrically connect the capacitor and the second source/drain region of the semiconductor substrate, wherein the capacitor contact penetrates through the mask layer.

In another embodiment of the present disclosure, a memory device is provided. The memory device includes a word line structure disposed in a semiconductor substrate. The word line structure includes a lower gate electrode layer, and an upper gate electrode layer disposed over and in direct contact with the lower gate electrode layer. A work function of the lower gate electrode layer is higher than a work function of the upper gate electrode layer. In addition, the word line structure includes a gate dielectric layer surrounding the lower gate electrode layer and the upper gate electrode layer. The memory device also includes a first source/drain region and a second source/drain region disposed in the semiconductor substrate and at opposite sides of the word line structure. The memory device further includes a bit line structure disposed over and electrically connected to the first source/drain region, and a capacitor disposed over and electrically connected to the second source/drain region.

In an embodiment, the lower gate electrode layer includes titanium nitride (TiN), and the upper gate electrode layer includes polysilicon. In an embodiment, the lower gate electrode layer is in direct contact with the gate dielectric layer, and the upper gate electrode layer is separated from the gate dielectric layer. In an embodiment, the lower gate electrode layer is surrounded by a lower portion of the gate dielectric layer, and the upper gate electrode layer is surrounded by an upper portion of the gate dielectric layer, and wherein a thickness of the lower portion of the gate dielectric layer is greater than a thickness of the upper portion of the gate dielectric layer.

In an embodiment, the word line structure further includes a pair of spacers disposed on opposite sides of the upper gate electrode layer, wherein the pair of spacers are sandwiched between the upper portion of the gate dielectric layer and the upper gate electrode layer. In an embodiment, the pair of spacers are in direct contact with the upper portion of the gate dielectric layer and the upper gate electrode layer. In an embodiment, the pair of spacers are in direct contact with a top surface of the lower gate electrode layer. In an embodiment, the memory device further includes a dielectric cap layer disposed over the semiconductor substrate, wherein a portion of the dielectric cap layer extends into the semiconductor substrate to cover the word line structure.

In an embodiment, the dielectric cap layer is in direct contact with the upper gate electrode layer. In an embodiment, the memory device further includes a lining layer disposed between the gate dielectric layer and the dielectric cap layer. In an embodiment, a top surface of the lining layer is higher than a top surface of the gate dielectric layer. In an embodiment, the upper gate electrode layer is separated from the dielectric cap layer by the lining layer.

In yet another embodiment of the present disclosure, a method for preparing a memory device is provided. The method includes forming a doped region in a semiconductor substrate, and forming a trench penetrating through the doped region such that a first source/drain region and a second source/drain region are formed at opposite sides of the trench. The method also includes forming a gate dielectric layer and a lower gate electrode layer in the trench. The lower gate electrode layer is surrounded by a lower portion of the gate dielectric layer. The method further includes forming a pair of spacers in the trench and on sidewalls of an upper portion of the gate dielectric layer, and forming an upper gate electrode layer over the lower gate electrode layer and surrounded by the pair of spacers. In addition, the method includes etching the upper gate electrode layer and the pair of spacers to form a recess partially exposing the sidewalls of the upper portion of the gate dielectric layer. The method also includes forming a bit line structure over and electrically connected to the first source/drain region, and forming a capacitor over and electrically connected to the second source/drain region.

In an embodiment, the method further includes partially removing the upper portion of the gate dielectric layer before the pair of spacers are formed on the sidewalls of the upper portion of the gate dielectric layer. In an embodiment, a thickness of the lower portion of the gate dielectric layer is greater than a thickness of the upper portion of the gate dielectric layer after the upper portion of the gate dielectric layer is partially removed. In an embodiment, a work function of the lower gate electrode layer is greater than a work function of the upper gate electrode layer.

In an embodiment, the step of forming the pair of spacers includes forming a spacer layer covering the gate dielectric layer and the lower gate electrode layer, and etching the spacer layer to form the pair of spacers and to expose a top surface of the lower gate electrode layer. In an embodiment, a top surface of the upper portion of the gate dielectric layer is covered by the pair of spacers before the upper gate electrode layer is formed. In an embodiment, the top surface of the upper portion of the gate dielectric layer is exposed after the upper gate electrode layer and the pair of spacers are etched.

In an embodiment, the method further includes forming a lining layer in the recess and covering the sidewalls of the upper portion of the gate dielectric layer. In an embodiment, the method further includes forming a dielectric cap layer over the semiconductor substrate, wherein a portion of the dielectric cap layer is in the recess and surrounded by the lining layer. In an embodiment, the upper gate electrode layer is separated from the dielectric cap layer by the lining layer. In an embodiment, the method further includes etching the lining layer to expose a top surface of the upper gate electrode layer before the dielectric cap layer is formed.

Embodiments of a memory device and method for preparing the same are provided in the disclosure. In some embodiments, the memory device includes a word line structure disposed in a semiconductor substrate. The word line structure includes a lower gate electrode layer, an upper gate electrode layer disposed over the lower gate electrode layer, and a pair of spacers disposed on opposite sides of the upper gate electrode layer. In some embodiments, the lower gate electrode layer and the upper gate electrode layer have different work functions. Therefore, gate induced drain leakage (GIDL) current can be reduced, which results in an increase of the turn-on speed and an increase of the write speed of the memory device. As a result, the performance of the memory device can be improved.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRA WINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

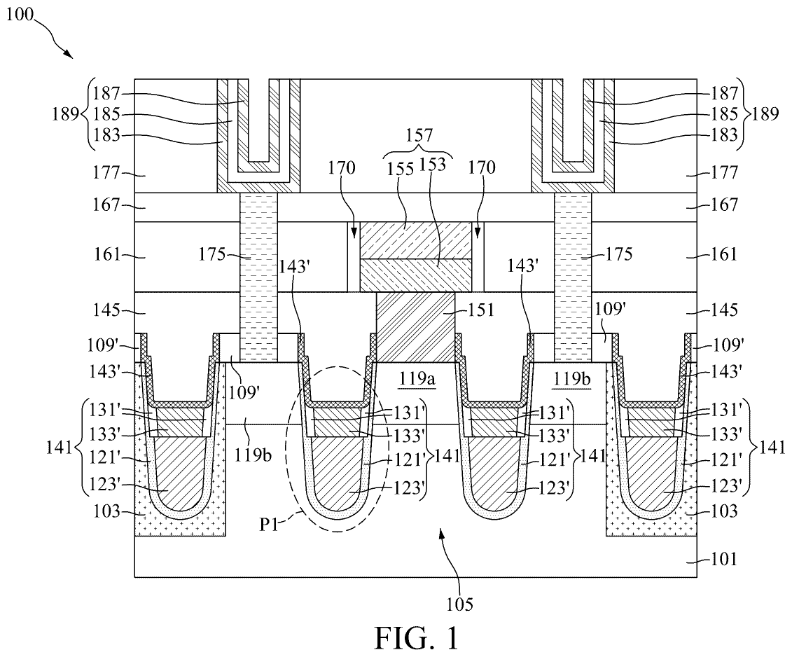

FIG. 1 is a cross-sectional view illustrating a memory device, in accordance with some embodiments.

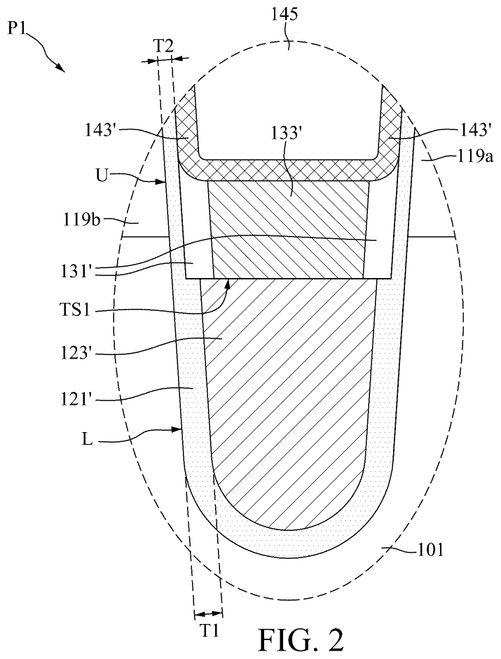

FIG. 2 is an enlarged view of a portion of the memory device in FIG. 1, in accordance with some embodiments.

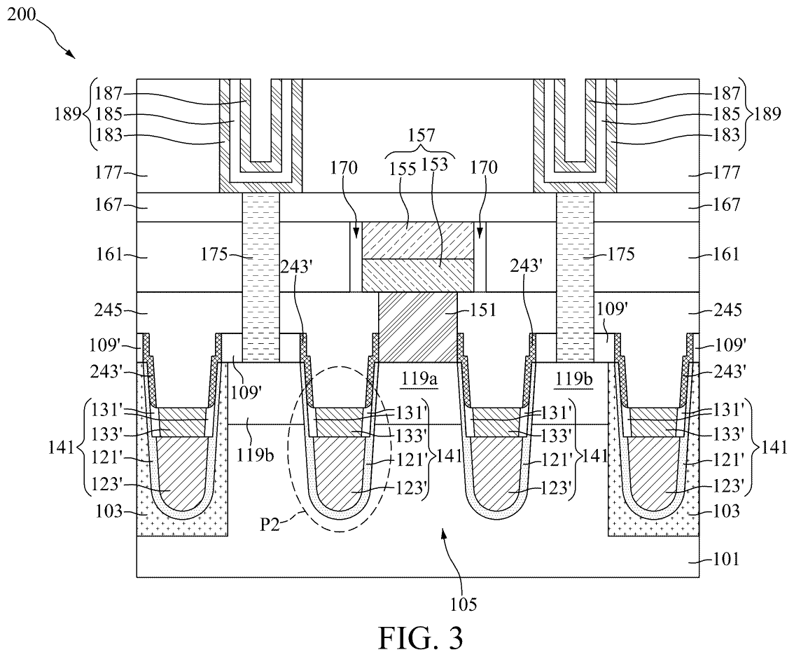

FIG. 3 is a cross-sectional view illustrating a memory device, in accordance with some alternative embodiments.

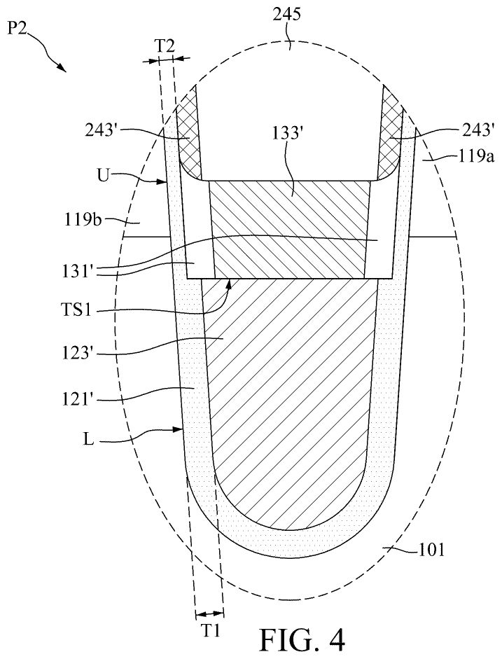

FIG. 4 is an enlarged view of a portion of the memory device in FIG. 3, in accordance with some alternative embodiments.

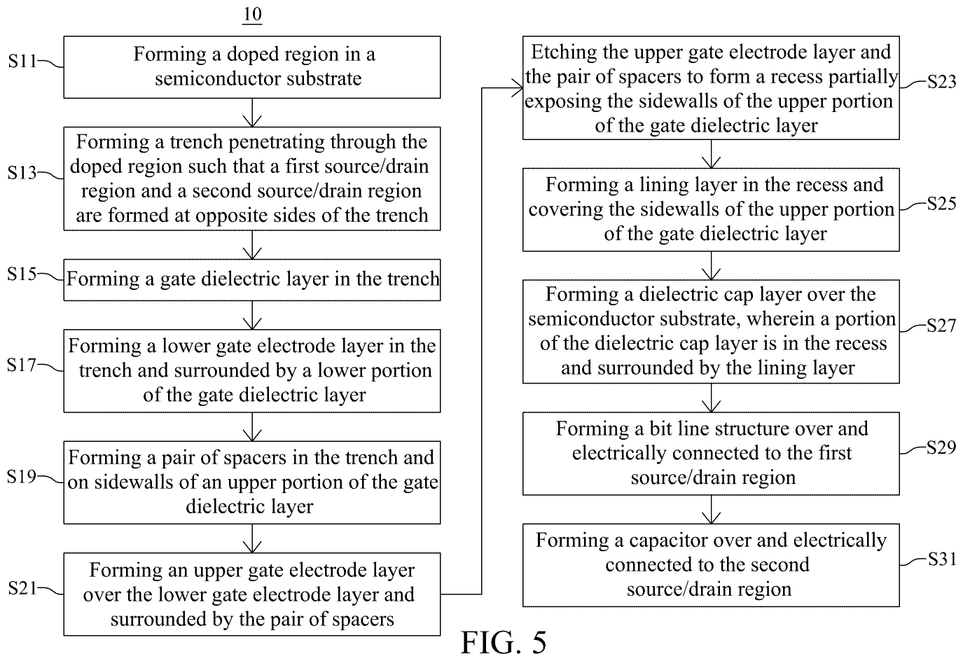

FIG. 5 is a flow diagram illustrating a method for preparing a memory device, in accordance with some embodiments.

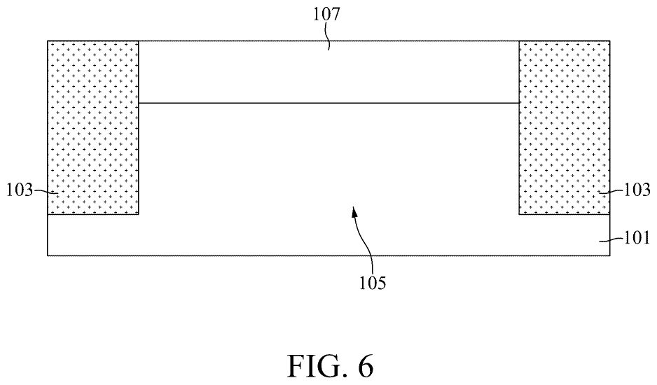

FIG. 6 is a cross-sectional view illustrating an intermediate stage of forming a doped region in a semiconductor substrate during the formation of the memory device, in accordance with some embodiments.

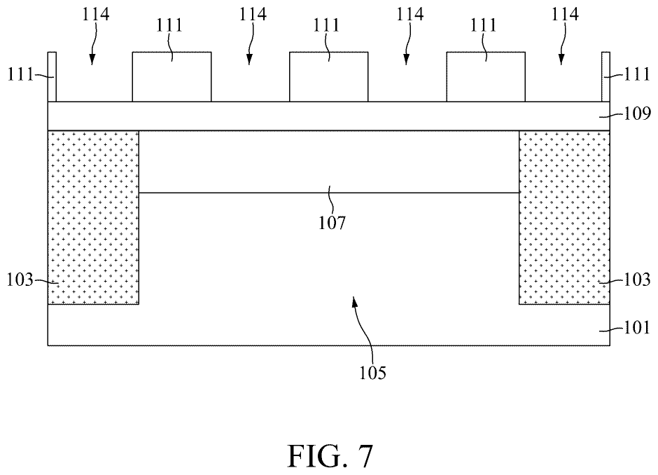

FIG. 7 is a cross-sectional view illustrating an intermediate stage of sequentially forming a mask layer and a patterned mask over the semiconductor substrate during the formation of the memory device, in accordance with some embodiments.

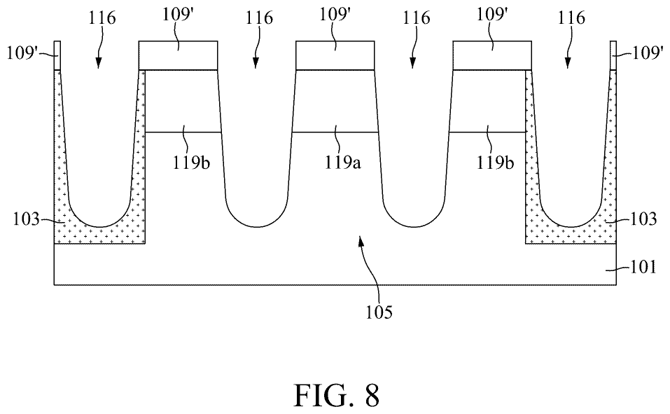

FIG. 8 is a cross-sectional view illustrating an intermediate stage of forming trenches in the semiconductor substrate during the formation of the memory device, in accordance with some embodiments.

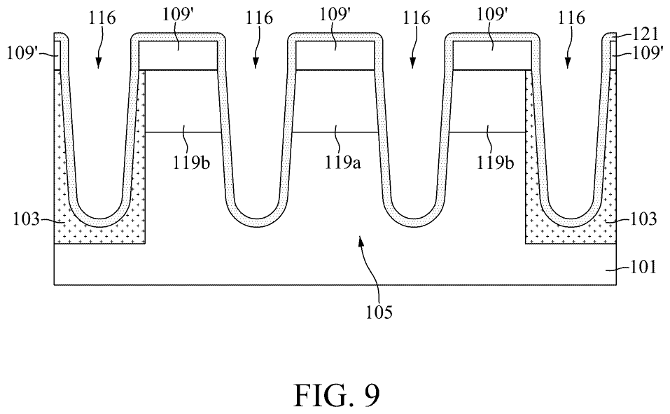

FIG. 9 is a cross-sectional view illustrating an intermediate stage of forming a gate dielectric layer in the trenches and over the mask layer during the formation of the memory device, in accordance with some embodiments.

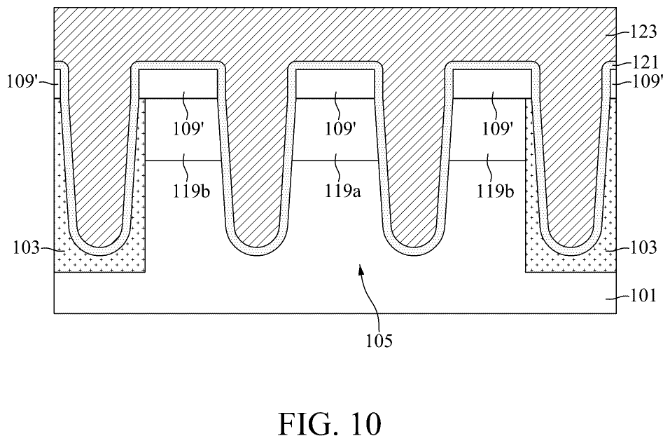

FIG. 10 is a cross-sectional view illustrating an intermediate stage of forming a lower gate electrode layer in the trenches and over the mask layer during the formation of the memory device, in accordance with some embodiments.

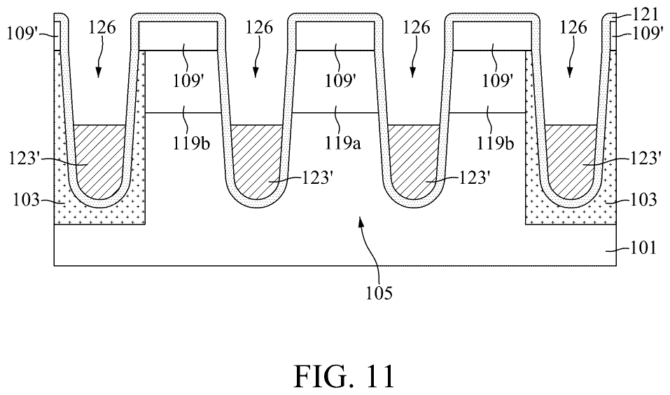

FIG. 11 is a cross-sectional view illustrating an intermediate stage of etching the lower gate electrode layer to form recesses during the formation of the memory device, in accordance with some embodiments.

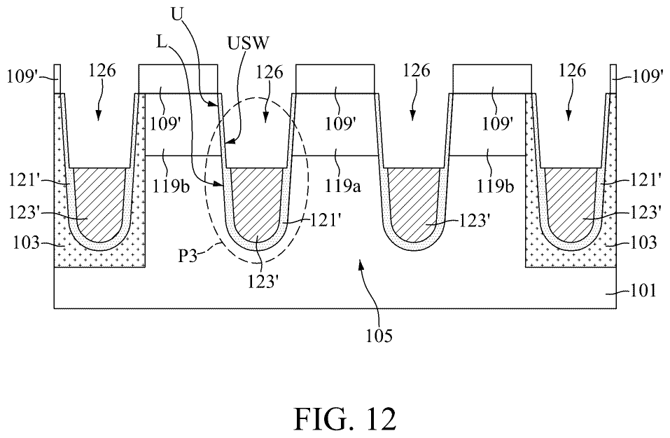

FIG. 12 is a cross-sectional view illustrating an intermediate stage of etching the gate dielectric layer during the formation of the memory device, in accordance with some embodiments.

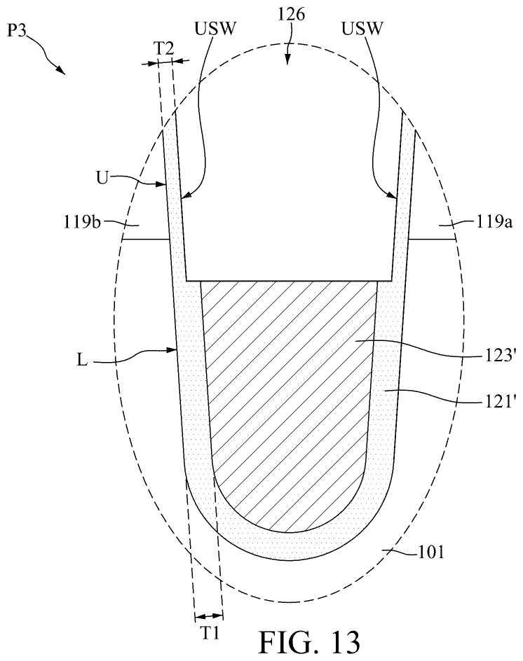

FIG. 13 is an enlarged view of a portion of the structure in FIG. 12, in accordance with some embodiments.

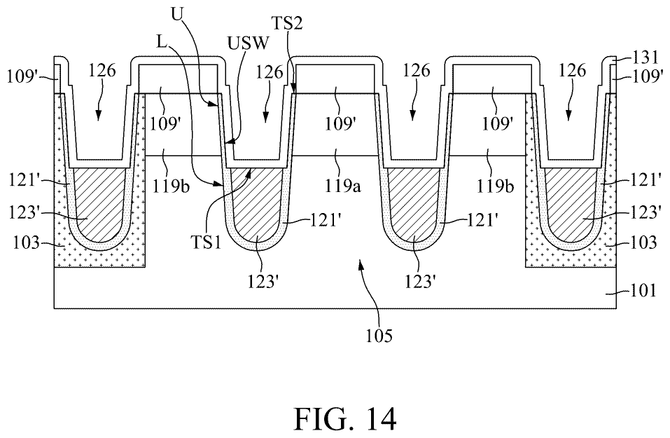

FIG. 14 is a cross-sectional view illustrating an intermediate stage of forming a spacer layer over the lower gate electrode layer, the gate dielectric layer, and the mask layer during the formation of the memory device, in accordance with some embodiments.

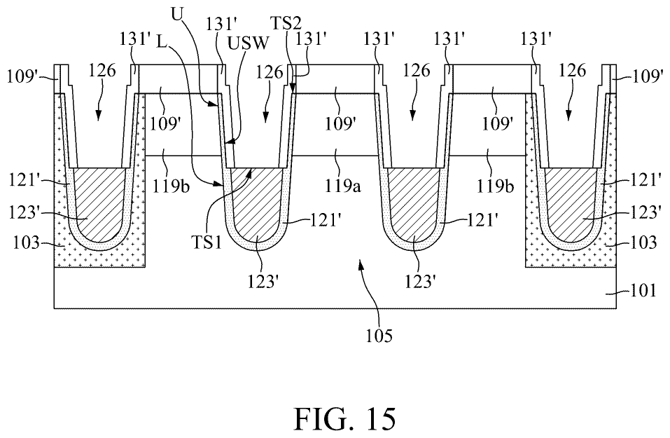

FIG. 15 is a cross-sectional view illustrating an intermediate stage of etching the spacer layer to form pairs of spacers lining the recesses during the formation of the memory device, in accordance with some embodiments.

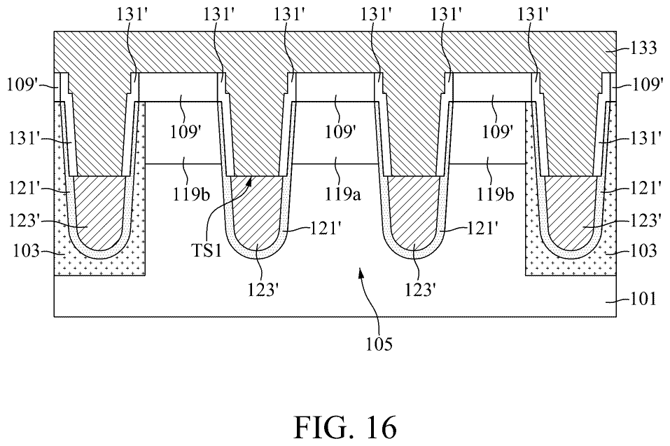

FIG. 16 is a cross-sectional view illustrating an intermediate stage of forming an upper gate electrode layer in the recesses and over the mask layer during the formation of the memory device, in accordance with some embodiments.

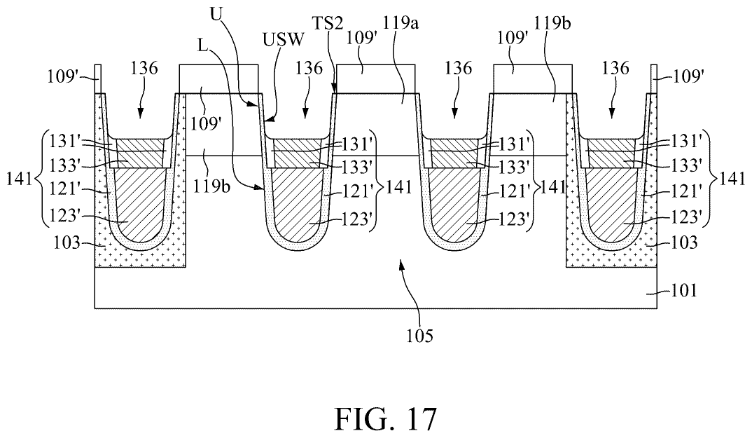

FIG. 17 is a cross-sectional view illustrating an intermediate stage of etching the pairs of spacers and the upper gate electrode layer to form recesses during the formation of the memory device, in accordance with some embodiments.

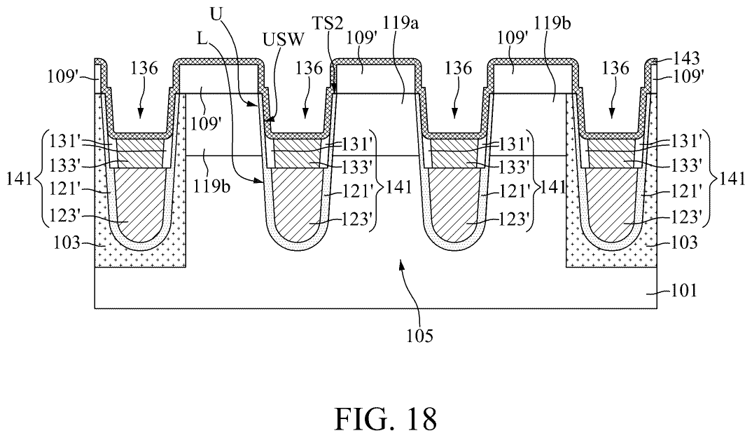

FIG. 18 is a cross-sectional view illustrating an intermediate stage of forming a lining layer in the recesses and over the mask layer during the formation of the memory device, in accordance with some embodiments.

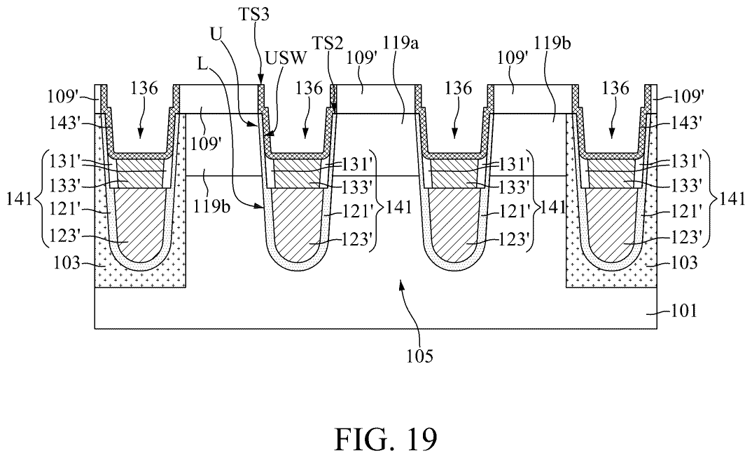

FIG. 19 is a cross-sectional view illustrating an intermediate stage of etching the lining layer to expose the mask layer during the formation of the memory device, in accordance with some embodiments.

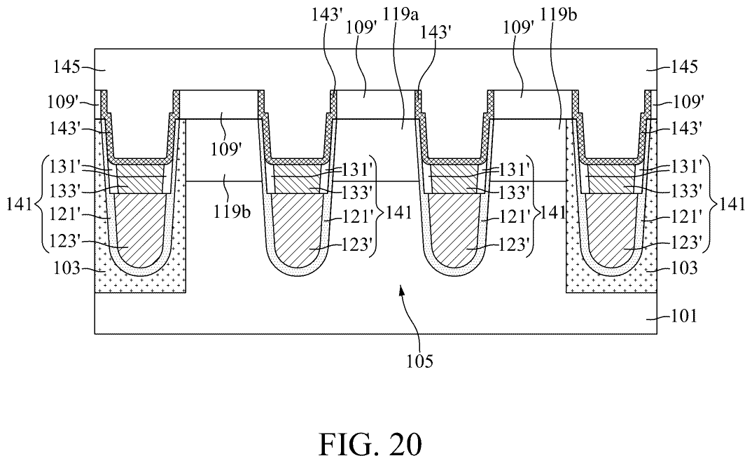

FIG. 20 is a cross-sectional view illustrating an intermediate stage of forming a dielectric cap layer in the recesses and over the mask layer during the formation of the memory device, in accordance with some embodiments.

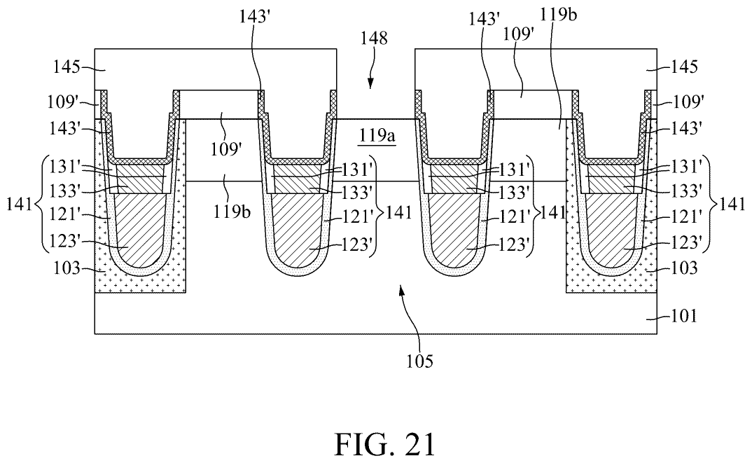

FIG. 21 is a cross-sectional view illustrating an intermediate stage of forming an opening penetrating through the dielectric cap layer during the formation of the memory device, in accordance with some embodiments.

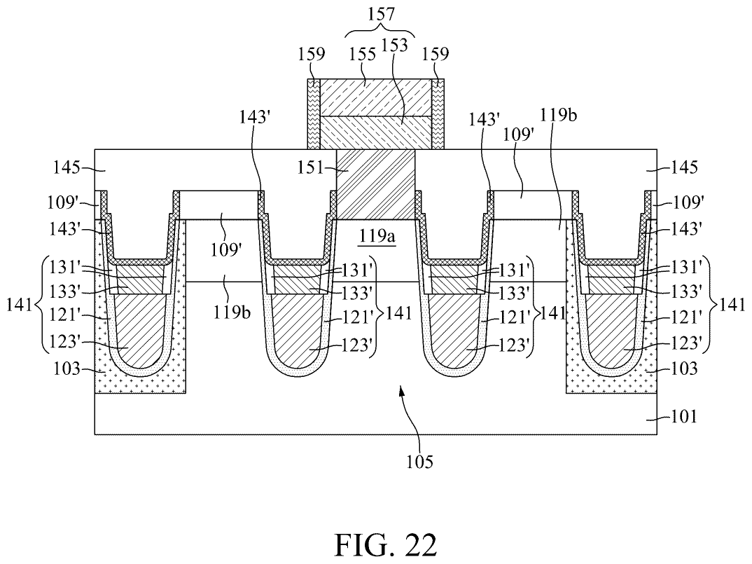

FIG. 22 is a cross-sectional view illustrating an intermediate stage of forming a bit line contact in the opening, forming a bit line structure over the bit line contact, and forming dielectric spacers on opposite sides of the bit line structure, in accordance with some embodiments.

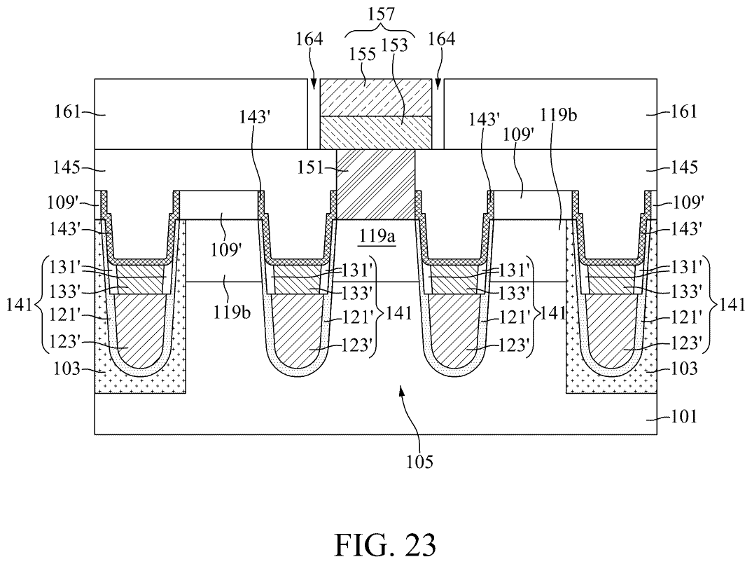

FIG. 23 is a cross-sectional view illustrating an intermediate stage of forming a dielectric layer surrounding the bit line structure, and removing the dielectric spacers, in accordance with some embodiments.

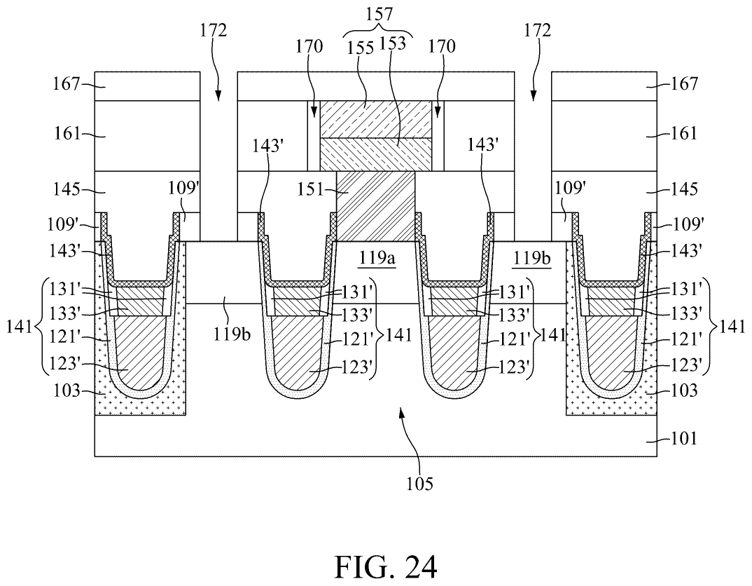

FIG. 24 is a cross-sectional view illustrating an intermediate stage of forming a dielectric layer covering the bit line structure, and forming openings penetrating through the mask layer, the dielectric cap layer and the dielectric layers, in accordance with some embodiments.

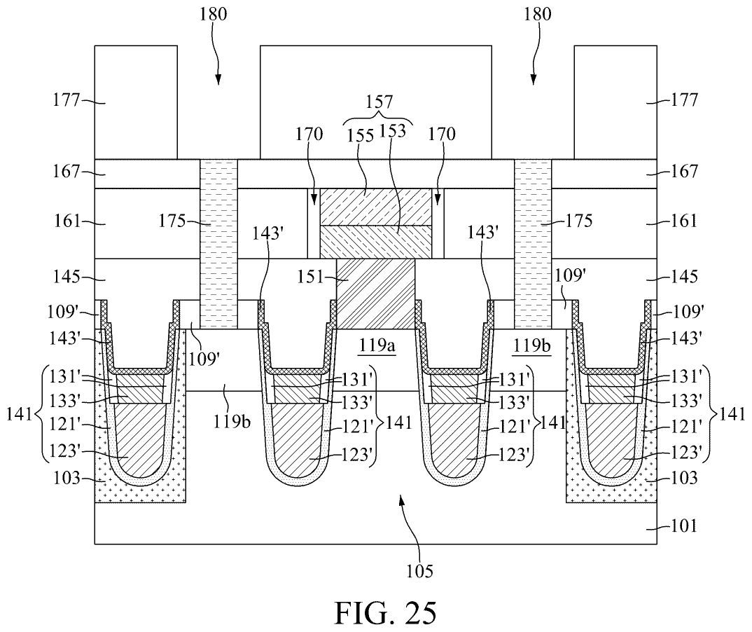

FIG. 25 is a cross-sectional view illustrating an intermediate stage of filling the openings with capacitor contacts, and forming a dielectric layer with openings exposing the capacitor contacts, in accordance with some embodiments.

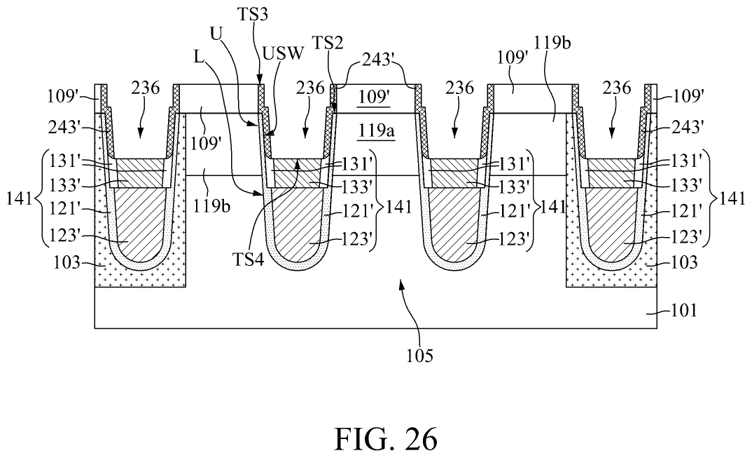

FIG. 26 is a cross-sectional view illustrating an intermediate stage of etching the lining layer to expose the mask layer during the formation of the memory device, in accordance with some alternative embodiments.

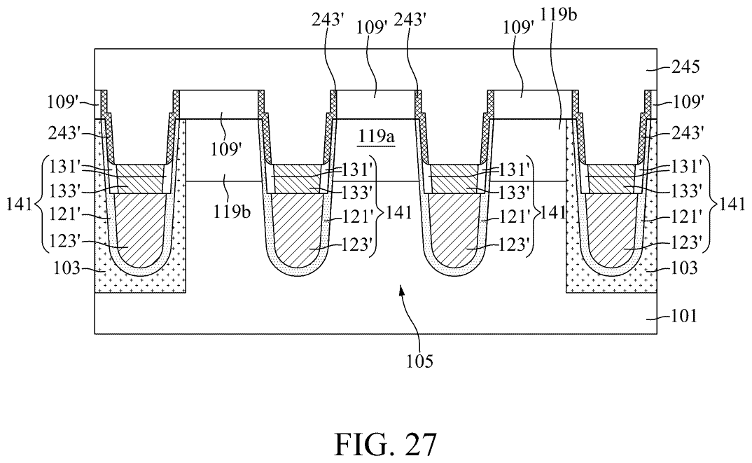

FIG. 27 is a cross-sectional view illustrating an intermediate stage of forming a dielectric cap layer in the recesses and over the mask layer during the formation of the memory device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

FIG. 1 is a cross-sectional view illustrating a memory device 100, in accordance with some embodiments. FIG. 2 is an enlarged view of a portion Pl of the memory device 100 in FIG. 1, in accordance with some embodiments.

As shown in FIGS. 1 and 2, the memory device 100 includes a semiconductor substrate 101, a plurality of isolation structures 103 disposed in the semiconductor substrate 101 defining an active area 105, a plurality of word line structures 141 (i.e., the gate structures) disposed in the semiconductor substrate 101, and a plurality of source/drain regions 119a, 119b in the active area 105 and separated by the word line structures 141, in accordance with some embodiments. In some embodiments, the active area 105 includes two source/drain regions 119b and one source/drain region 119a disposed between the source/drain regions 119b. Moreover, each of the word line structures 141 includes a gate dielectric layer 121′, a pair of spacers 131′, a lower gate electrode layer 123′, and an upper gate electrode layer 133′.

In some embodiments, the upper gate electrode layers 133′ are disposed over the lower gate electrode layers 123′. In some embodiments, the lower gate electrode layers 123′ and the upper gate electrode layers 133′ are surrounded by the gate dielectric layers 121′. In some embodiments, each pair of the spacers 131′ is disposed between the corresponding upper gate electrode layer 133′ and the corresponding gate dielectric layer 121′. In some embodiments, each of the upper gate electrode layers 133′ is surrounded by the corresponding pair of spacers 131′. In some embodiments, the upper gate electrode layers 133′ are separated from the gate dielectric layers 121′ by the pairs of spacers 131′.

In some embodiments, the memory device 100 includes a plurality of mask layers 109′ disposed over the semiconductor substrate 101. In some embodiments, the source/drain regions 119b are covered by the mask layers 109′. In some embodiments, the memory device 100 includes a plurality of lining layers 143′. In some embodiments, the sidewalls of the mask layers 109′ are covered by and in direct contact with the lining layers 143′. In the present embodiment, the gate dielectric layers 121′, the pairs of spacers 131′ and the upper gate electrode layers 133′ of the word line structures 141 are covered by and in direct contact with the lining layers 143′.

In some embodiments, the memory device 100 includes a dielectric cap layer 145 covering the mask layers 109′ and the lining layers 143′. In the present embodiment, the gate dielectric layers 121′, the pairs of spacers 131′ and the upper gate electrode layers 133′ of the word line structures 141 are separated from the dielectric cap layer 145 by the lining layers 143′. In some embodiments, the memory device 100 includes a bit line contact 151 penetrating through the dielectric cap layer 145 to contact the source/drain region 119a. In some embodiments, the sidewalls of the bit line contact 151 are covered by and in direct contact with the lining layers 143′.

Moreover, the memory device 100 includes a dielectric layer 161 disposed over the dielectric cap layer 145, and a bit line structure 157 penetrating through the dielectric layer 161 to contact the bit line contact 151, in accordance with some embodiments. In some embodiments, the bit line structure 157 includes a lower bit line layer 153 and an upper bit line layer 155 disposed over the lower bit line layer 153. In some embodiments, the bit line structure 157 is separated from the dielectric layer 161 by air gaps 170.

In addition, the memory device 100 includes a dielectric layer 167 disposed over the dielectric layer 161, and a plurality of capacitor contacts 175 penetrating through the dielectric layer 167, the dielectric layer 161, the dielectric cap layer 145, and the mask layers 109′ to contact the source/drain regions 119b, in accordance with some embodiments. In some embodiments, the memory device 100 includes a dielectric layer 177 disposed over the dielectric layer 167. In some embodiments, the memory device 100 includes a plurality of capacitors 189 disposed in the dielectric layer 177 to contact the capacitor contacts 175.

In some embodiments, each of the capacitors 189 includes a bottom electrode 183, a top electrode 187 disposed over and surrounded by the bottom electrode 183, and a dielectric layer 185 disposed between and in direct contact with the bottom electrode 183 and the top electrode 187. In some embodiments, the bit line structure 157 is electrically connected to the source/drain region 119a through the bit line contact 151, and the capacitors 189 are electrically connected to the source/drain regions 119b through the capacitor contacts 175. In some embodiments, the memory device 100 is part of a DRAM.

In some embodiments, the lower gate electrode layers 123′ have a work function different from that of the upper gate electrode layers 133′. In some embodiments, the lower gate electrode layers 123′ have a work function greater than that of the upper gate electrode layers 133′. In some embodiments, the lower gate electrode layers 123′ include titanium nitride (TiN), and the upper gate electrode layers 133′ include polysilicon.

As shown in FIG. 2, in the portion PI of the memory device 100, the gate dielectric layer 121′ has a lower portion L surrounding the lower gate electrode layer 123′ and an upper portion U surrounding the upper gate electrode layer 133′ and the pair of spacers 131′, in accordance with some embodiments. In some embodiments, the thickness T1 of the lower portion L of the gate dielectric layer 121′ is greater than the thickness T2 of the upper portion U of the gate dielectric layer 121′.

In addition, the pair of spacers 131′ and the upper gate electrode layer 133′ are in direct contact with the top surface TS1 of the lower gate electrode layer 123′, as shown in FIG. 2 in accordance with some embodiments. It should be noted that, the above-mentioned features also present in other word line structures 141 not shown in the enlarged view of FIG. 2, and are not repeated herein.

FIG. 3 is a cross-sectional view illustrating a memory device 200, in accordance with some alternative embodiments. FIG. 4 is an enlarged view of a portion P2 of the memory device in FIG. 3, in accordance with some alternative embodiments. The memory device 200 is similar to the memory device 100. However, in the memory device 200, the upper gate electrode layers 133′ and the pairs of spacers 131′ of the word line structures 141 are in direct contact with the dielectric cap layer 245, in accordance with some embodiments.

In the embodiment shown in FIGS. 3 and 4, the sidewalls of the mask layers 109′ and the sidewalls of the bit line contact 151 are covered by and in direct contact with the lining layers 243′, and the pairs of spacers 131′ are in direct contact with both the lining layers 243′ and the dielectric cap layer 245.

As shown in FIG. 4, in the portion P2 of the memory device 200, the gate dielectric layer 121′ has a lower portion L surrounding the lower gate electrode layer 123′ and an upper portion U surrounding the upper gate electrode layer 133′ and the pair of spacers 131′, in accordance with some embodiments. In some embodiments, the thickness T1 of the lower portion L of the gate dielectric layer 121′ is greater than the thickness T2 of the upper portion U of the gate dielectric layer 121′.

In addition, the pair of spacers 131′ and the upper gate electrode layer 133′ are in direct contact with the top surface TS1 of the lower gate electrode layer 123′, as shown in FIG. 4 in accordance with some embodiments. It should be noted that, the above-mentioned features also present in other word line structures 141 not shown in the enlarged view of FIG. 4, and are not repeated herein.

Embodiments of the memory devices 100 and 200 and methods for preparing the same are provided in the disclosure. In some embodiments, both of the memory devices 100 and 200 include the word line structures 141 disposed in the semiconductor substrate 101, and the word line structures 141 include the lower gate electrode layers 123′ and the upper gate electrode layers 133′ with different work functions, and pairs of spacers 131′ disposed on opposite sides of the upper gate electrode layers 133′. Therefore, gate induced drain leakage (GIDL) current can be reduced, which results in an increase of the turn-on speed and an increase of the write speed of the memory devices 100 and 200. In addition, the air gaps 170 surrounding the bit line structures 157 may help to reduce parasitic capacitance and correspondingly improve device performance (e.g., by reducing signal noise). As a result, the performance of the memory devices 100 and 200 can be improved.

FIG. 5 is a flow diagram illustrating a method 10 for preparing the memory device 100, and the method 10 includes steps S11, S13, S15, S17, S19, S21, S23, S25, S27, S29 and S31, in accordance with some embodiments. The steps S11 to S31 of FIG. 5 are elaborated in connection with FIGS. 6 to 27.

FIGS. 6 to 25 are cross-sectional views illustrating intermediate stages in the formation of the memory device 100, in accordance with some embodiments. As shown in FIG. 6, a semiconductor substrate 101 is provided.

The semiconductor substrate 101 may be a semiconductor wafer such as a silicon wafer. Alternatively or additionally, the semiconductor substrate 101 may include elementary semiconductor materials, compound semiconductor materials, and/or alloy semiconductor materials. Examples of the elementary semiconductor materials may include, but are not limited to, crystal silicon, polycrystalline silicon, amorphous silicon, germanium, and/or diamond. Examples of the compound semiconductor materials may include, but are not limited to, silicon carbide, gallium arsenic, gallium phosphide, indium phosphide, indium arsenide, and/or indium antimonide. Examples of the alloy semiconductor materials may include, but are not limited to, SiGe, GaAsP, AlInAs, AlGaAs, GaInAs, GaInP, and/or GaInAsP.

In some embodiments, the semiconductor substrate 101 includes an epitaxial layer. For example, the semiconductor substrate 101 has an epitaxial layer overlying a bulk semiconductor. In some embodiments, the semiconductor substrate 101 is a semiconductor-on-insulator substrate which may include a substrate, a buried oxide layer over the substrate, and a semiconductor layer over the buried oxide layer, such as a silicon-on-insulator (SOI) substrate, a silicon germanium-on-insulator (SGOI) substrate, or a germanium-on-insulator (GOI) substrate. Semiconductor-on-insulator substrates can be fabricated using separation by implantation of oxygen (SIMOX), wafer bonding, and/or other suitable methods.

Still referring to FIG. 6, isolation structures 103 are formed in the semiconductor substrate 101 to define an active area 105, and the isolation structures 103 are shallow trench isolation (STI) structures, in accordance with some embodiments. In addition, the isolation structures 103 may include silicon oxide, silicon nitride, silicon oxynitride or another suitable dielectric material. The formation of the isolation structures 103 may include forming a patterned mask (not shown) over the semiconductor substrate 101, etching the semiconductor substrate 101 to form openings (not shown) by using the patterned mask as a mask, depositing a dielectric material in the openings and over the semiconductor substrate 101, and planarizing the dielectric material until the semiconductor substrate 101 is exposed.

Moreover, a doped region 107 is formed in the active area 105 defined by the isolation structures 103, as shown in FIG. 6 in accordance with some embodiments. The respective step is illustrated as the step S11 in the method 10 shown in FIG. 5. In some embodiments, the doped region 107 is formed by one or more ion implantation processes, and P-type dopants, such as boron (B), gallium (Ga), or indium (In), or N-type dopants, such as phosphorous (P) or arsenic (As), can be implanted in the active area 105 to form the doped region 107, depending on the conductivity type of the memory device 100. In addition, the doped region 107 will become the source/drain regions of the memory device 100 in the subsequent processes.

After the doped region 107 is formed, a mask layer 109 is formed over the semiconductor substrate 101, as shown in FIG. 7 in accordance with some embodiments. In some embodiments, the isolation structures 103 and the doped region 107 are covered by the mask layer 109. Then, a patterned mask 111 with a plurality of openings 114 is formed over the mask layer 109, in accordance with some embodiments. In some embodiments, the mask layer 109 is partially exposed by the openings 114 of the patterned mask 111.

In some embodiments, the mask layer 109 includes silicon nitride, silicon oxide, silicon oxynitride, another suitable material, or a combination thereof. In some embodiments, the mask layer 109 and the patterned mask 111 include different materials so that the etching selectivities may be different in the subsequent etching process. In some embodiments, the mask layer 109 is formed by a deposition process, such as a chemical vapor deposition (CVD) process, a physical vapor deposition (PVD) process, an atomic layer deposition (ALD) process, a spin-on coating process, or another suitable deposition process.

Next, the mask layer 109, the isolation structures 103 and the semiconductor substrate 101 are etched to form a plurality of trenches 116 by using the patterned mask 111 as an etching mask, as shown in FIG. 8 in accordance with some embodiments. In some embodiments, the trenches 116 penetrate through the mask layer 109 and the doped region 107 in the active area 105, such that the source/drain regions 119a and 119b are obtained. It some embodiments, the source/drain region 119a is referred to as a first source/drain region, and the source/drain regions 119b are referred to as second source/drain regions.

In some embodiments, the source/drain regions 119b are located at the opposite end portions of the active area 105, and the source/drain region 119a is located at the middle portion of the active area 105. In some embodiments, the remaining portions of the mask layer 109 are referred to as mask layers 109′. The respective step is illustrated as the step S13 in the method 10 shown in FIG. 5.

In some embodiments, the trenches 116 are formed by a wet etching process, a dry etching process, or a combination thereof. After the trenches 116 are formed, the patterned mask 111 may be removed. In some embodiments, the patterned mask 111 is removed by a stripping process, an ashing process, an etching process, or another suitable process.

Subsequently, a gate dielectric layer 121 is formed in the trenches 116 and over the mask layers 109′, as shown in FIG. 9 in accordance with some embodiments. In some embodiments, the sidewalls of the trenches 116 and the top surfaces of the mask layers 109′ are covered by the gate dielectric layer 121. In some embodiments, the gate dielectric layer 121 includes silicon oxide, silicon nitride, silicon oxynitride, a dielectric material with high dielectric constant (high-k), or a combination thereof. In some embodiments, the gate dielectric layer 121 is formed by a deposition process, such as a CVD process, a PVD process, an ALD process, a spin-on coating process, or another suitable deposition process.

Then, a lower gate electrode layer 123 is formed over the gate dielectric layer 121, as shown in FIG. 10 in accordance with some embodiments. In some embodiments, the remaining portions of the trenches 116 over the gate dielectric layer 121 are filled by the lower gate electrode layer 123, and the lower gate electrode layer 123 extends over the top surfaces of the mask layers 109′.

In some embodiments, the lower gate electrode layer 123 includes titanium nitride (TiN). However, any other suitable conductive materials may be utilized, such as aluminum (Al), copper (Cu), tungsten (W), titanium (Ti), or tantalum (Ta). In some embodiments, the lower gate electrode layer 123 is formed by a deposition process, such as a CVD process, a PVD process, an ALD process, a sputtering process, a plating process, or another suitable deposition process.

Next, the lower gate electrode layer 123 is partially removed by an etch back process, as shown in FIG. 11 in accordance with some embodiments. In some embodiments, the etch back process includes a wet etching process, a dry etching process, or a combination thereof. After the etch back process is performed, the remaining portions of the lower gate electrode layer 123 are referred to as lower gate electrode layers 123′, and the gate dielectric layer 121 is partially exposed by recesses 126 over the lower gate electrode layers 123′, in accordance with some embodiments.

Subsequently, the portions of the gate dielectric layer 121 exposed by the lower gate electrode layers 123′ are partially removed by a cleaning process, as shown in FIG. 12 in accordance with some embodiments. After the cleaning process is performed, the remaining portions of the gate dielectric layer 121 are referred to as gate dielectric layers 121′, and the mask layers 109′ are exposed, in accordance with some embodiments. In some embodiments, the top surfaces and the sidewalls of the mask layers 109′ are exposed after the cleaning process is performed.

In some embodiments, each of the gate dielectric layers 121′ includes an upper portion U surrounding the corresponding recess 126 and a lower portion L surrounding the corresponding lower gate electrode layer 123′. In some embodiments, the sidewalls USW of the upper portions U of the gate dielectric layers 121′ are exposed by the recesses 126. The respective steps are illustrated as the steps S15 and S17 in the method 10 shown in FIG. 5.

FIG. 13 is an enlarged view of a portion P3 of the structure in FIG. 12, in accordance with some embodiments. As shown in FIGS. 12 and 13, in the portion P3, the sidewalls USW of the upper portion U of the gate dielectric layer 121′ are exposed by the recess 126, in accordance with some embodiments. Moreover, after the cleaning process is performed, the thickness T1 of the lower portion L of the gate dielectric layer 121′ is greater than the thickness T2 of the upper portion U of the gate dielectric layer 121′, in accordance with some embodiments. In some embodiments, the cleaning process includes a wet etching process, a dry etching process, or a combination thereof. It should be noted that, the above-mentioned features also present in other gate dielectric layers 121′ not shown in the enlarged view of FIG. 13, and are not repeated herein.

Then, a spacer layer 131 is formed covering the mask layers 109′, the gate dielectric layers 121′, and the lower gate electrode layers 123′, as shown in FIG. 14 in accordance with some embodiments. In some embodiments, the top surfaces and the sidewalls of the mask layers 109′ are covered by and in direct contact with the spacer layer 131. In some embodiments, the sidewalls USW of the upper portions U of the gate dielectric layers 121′ and the top surfaces TS2 of the gate dielectric layers 121′ are covered by and in direct contact with the spacer layer 131. In some embodiments, the top surfaces TS1 of the lower gate electrode layers 123′ are covered by and in direct contact with the spacer layer 131.

In some embodiments, the spacer layer 131 includes silicon oxide. However, any other suitable materials may be utilized, such as silicon nitride or silicon oxynitride. In some embodiments, the spacer layer 131 is formed by a deposition process, such as an ALD process. However, any other deposition processes may be utilized, such as CVD or PVD process.

Next, an etching process is performed on the spacer layer 131 to form pairs of spacers 131′ in the recesses 126, as shown in FIG. 15 in accordance with some embodiments. In some embodiments, the sidewalls USW of the upper portions U of the gate dielectric layers 121′ are covered by and in direct contact with the pairs of spacers 131′. The respective step is illustrated as the step S19 in the method 10 shown in FIG. 5.

In some embodiments, the top surfaces of the mask layers 109′ are exposed after the pairs of spacers 131′ are formed. In some embodiments, the top surfaces TS1 of the lower gate electrode layers 123′ are at least partially exposed by the recesses 126. In some embodiments, the pairs of spacers 131′ are in direct contact with the top surfaces TS1 of the lower gate electrode layers 123′. In some embodiments, the top surfaces TS2 of the gate dielectric layers 121′ are covered by and in direct contact with the pair of spacers 131′. In some embodiments, the etching process includes a wet etching process, a dry etching process, or a combination thereof.

Subsequently, an upper gate electrode layer 133 is formed in the recesses 126 and over the mask layers 109′, as shown in FIG. 16 in accordance with some embodiments. In some embodiments, the top surfaces TS1 of the lower gate electrode layers 123′ are covered by and in direct contact with the upper gate electrode layer 133. In some embodiments, the portions of the upper gate electrode layer 133 filled into the recesses 126 are surrounded by the pairs of spacers 131′. The respective step is illustrated as the step S21 in the method 10 shown in FIG. 5.

In some embodiments, the upper gate electrode layer 133 has a work function different than that of the lower gate electrode layers 123′. In some embodiments, the upper gate electrode layer 133 has a work function less than that of the lower gate electrode layers 123′. In some embodiments, the upper gate electrode layer 133 includes polysilicon. However, any other suitable conductive materials may be utilized, such as aluminum (Al), copper (Cu), tungsten (W), titanium (Ti), or tantalum (Ta). In some embodiments, the upper gate electrode layer 133 is formed by a deposition process, such as a CVD process, a PVD process, an ALD process, a sputtering process, a plating process, or another suitable deposition process.

Then, an etching process is performed on the upper gate electrode layer 133 and the pairs of spacers 131′ to expose the top surfaces TS2 of the gate dielectric layers 121′, as shown in FIG. 17 in accordance with some embodiments. In some embodiments, the sidewalls USW of the upper portions U of the gate dielectric layers 121′ are partially exposed by recesses 136 after the etching process is performed. In some embodiments, the remaining portions of the upper gate electrode layer 133 are referred to as upper gate electrode layers 133′, and each of the upper gate electrode layers 133′ is surrounded by the corresponding pair of spacers 131′.

In some embodiments, the etching process includes a wet etching process, a dry etching process, or a combination thereof. In some embodiments, the word line structures 141 including the gate dielectric layers 121′, the lower gate electrode layers 123′, the pairs of spacers 131′ and the upper gate electrode layers 133′ are obtained after the etching process is performed. The respective step is illustrated as the step S23 in the method 10 shown in FIG. 5.

Next, a lining layer 143 is formed covering the mask layers 109′ and the word line structures 141, as shown in FIG. 18 in accordance with some embodiments. In some embodiments, the top surfaces and the sidewalls of the mask layers 109′ are covered by and in direct contact with the lining layer 143. In some embodiments, the sidewalls USW of the upper portions U of the gate dielectric layers 121′ and the top surfaces TS2 of the gate dielectric layers 121′ are covered by and in direct contact with the lining layer 143.

In some embodiments, the lining layer 143 includes silicon oxide. However, any other suitable materials may be utilized, such as silicon nitride or silicon oxynitride. In some embodiments, the lining layer 143 is formed by a deposition process, such as an ALD process. However, any other deposition processes may be utilized, such as CVD or PVD process.

Subsequently, an etching process is performed on the lining layer 143 to expose the top surfaces of the mask layers 109′, as shown in FIG. 19 in accordance with some embodiments. In some embodiments, the remaining portions of the lining layer 143 are referred to as lining layers 143′. In some embodiments, the word line structures 141 are covered by the lining layers 143′.

In some embodiments, the sidewalls USW of the upper portions U of the gate dielectric layers 121′ and the top surfaces TS2 of the gate dielectric layers 121′ are covered by and in direct contact with the lining layers 143′. In some embodiments, the top surfaces TS3 of the lining layers 143′ are higher than the top surfaces TS2 of the gate dielectric layers 121′. In some embodiments, the etching process includes a wet etching process, a dry etching process, or a combination thereof. The respective step is illustrated as the step S25 in the method 10 shown in FIG. 5.

Then, a dielectric cap layer 145 is formed covering the mask layers 109′ and the lining layers 143′, as shown in FIG. 20 in accordance with some embodiments. In some embodiments, the dielectric cap layer 145 has portions extending into the recesses 136 and surrounded by the lining layers 143′. The respective step is illustrated as the step S27 in the method 10 shown in FIG. 5.

In some embodiments, the dielectric cap layer 145 includes silicon nitride. However, any other suitable materials may be utilized, such as silicon oxide or silicon oxynitride. In some embodiments, the dielectric cap layer 145 is formed by a deposition process, such as a CVD process, a PVD process, an ALD process, a spin-on coating process, or another suitable deposition process.

Next, an opening 148 is formed to expose the source/drain region 119a, as shown in FIG. 21 in accordance with some embodiments. In some embodiments, the mask layer 109′ and the portion of the dielectric cap layer 145 over the source/drain region 119a are removed to form the opening 148. In some embodiments, the lining layers 143′ are exposed by the opening 148.

The formation of the opening 148 may include forming a patterned mask (not shown) over the dielectric cap layer 145, and performing an etching process by using the patterned mask as a mask. The etching process may be a wet etching process, a dry etching process, or a combination thereof. After the opening 148 is formed, the pattered mask may be removed.

Subsequently, a bit line contact 151 is formed in the opening 148, and a bit line structure 157 is formed over the bit line contact 151, as shown in FIG. 22 in accordance with some embodiments. In some embodiments, the bit line structure 157 includes a lower bit line layer 153 and an upper bit line layer 155 disposed over the lower bit line layer 153. In some embodiments, the bit line structure 157 is electrically connected to the source/drain region 119a. The respective step is illustrated as the step S29 in the method 10 shown in FIG. 5.

In some embodiments, the bit line contact 151 includes polysilicon, W, Al, Cu, Ni, Co, another suitable conductive material, or a combination thereof. The formation of the bit line contact 151 may include depositing a bit line contact material (not shown) in the opening 148 and over the dielectric cap layer 145, and performing a planarization process to remove excess portions of the bit line contact material outside the opening 148. The deposition process may include a CVD process, a PVD process, an ALD process, a spin-on coating process, or another suitable deposition process. The planarization process may include a chemical mechanical polishing (CMP) process.

Moreover, the formation of the bit line structure 157 may include forming a lower bit line material (not shown) over the dielectric cap layer 145, forming an upper bit line material (not shown) over the lower bit line material, forming a patterned mask (not shown) over the upper bit line material, and etching the upper bit line material and the lower bit line material by using the patterned mask as a mask. In some embodiments, the remaining portion of the lower bit line material is referred to as the lower bit line layer 153, and the remaining portion of the upper bit line material is referred to as the upper bit line layer 155. After the bit line structure 157 is formed, the pattered mask may be removed. In some embodiments, the lower bit line layer 153 includes TiN, TaN, TaC, TiC, another suitable conductive material, or a combination thereof. In some embodiments, the upper bit line layer 155 includes W, Ti, Ni, Co, another suitable conductive material, or a combination thereof.

Still referring to FIG. 22, a pair of dielectric spacers 159 is formed on opposite sidewalls of the bit line structure 157, in accordance with some embodiments. In some embodiments, the pair of dielectric spacers 159 includes a doped spin-on-glass (SOG) material, such as phosphosilicate glass (PSG), borophosphosilicate glass (BPSG). In some embodiments, the pair of dielectric spacers 159 is formed by a deposition process, and a subsequent etching process. The deposition process may include a CVD process, a PVD process, an ALD process, a spin-on coating process, or another suitable deposition process. The etching process may include a wet etching process, a dry etching process, or a combination thereof.

Then, a dielectric layer 161 is formed surrounding the pair of dielectric spacers 159 and the bit line structure 157, and the pair of dielectric spacers 159 is removed to form gaps 164 between the bit line structure 157 and the dielectric layer 161, as shown in FIG. 23 in accordance with some embodiments. In some embodiments, the gaps 164 are formed on the opposite sidewalls of the bit line structure 157, and the bit line structure 157 is separated from the dielectric layer 161 by the gaps 164.

In some embodiments, the dielectric layer 161 includes silicon oxide, silicon nitride, silicon oxynitride, another suitable dielectric material, or a combination thereof. Moreover, the dielectric layer 161 is formed by a deposition process, and a subsequent planarization process. The deposition process may include a CVD process, a PVD process, an ALD process, a spin-on coating process, or another suitable deposition process. The planarization process may include a CMP process.

After the planarization process, the top surface of the dielectric layer 161 is substantially coplanar with the top surface of the bit line structure 157 and the top surfaces of the pair of dielectric spacers 159, in accordance with some embodiments. Within the context of this disclosure, the word “substantially” means preferably at least 90%, more preferably 95%, even more preferably 98%, and most preferably 99%.

In some embodiments, the pair of dielectric spacers 159 is removed by a vapor phase hydrofluoric acid (VHF) etching process after the dielectric layer 161 is formed. During the etching process, VHF is used as an etchant, and the pair of dielectric spacers 159 has a high selectivity against the dielectric layer 161. Therefore, the pair of dielectric spacers 159 is removed by the etching process, while the dielectric layer 161 may be substantially left, such that the gaps 164 are obtained.

Next, the dielectric layer 167 is formed over the dielectric layer 161 to seal the gaps 164, and a plurality of openings 172 are formed to expose the source/drain regions 119b, as shown in FIG. 24 in accordance with some embodiments. In some embodiments, the sealed gaps 164 are referred to as air gaps 170. Some materials and processes used to form the dielectric layer 167 are similar to, or the same as those used to form the dielectric layer 161, and details thereof are not repeated herein.

In some embodiments, the openings 172 are formed penetrating through the dielectric layer 167, the dielectric layer 161, the dielectric cap layer 145, and the mask layers 109′ over the source/drain regions 119b. The formation of the openings 172 may include forming a patterned mask (not shown) over the dielectric layer 167, and etching the dielectric layer 167, the dielectric layer 161, the dielectric cap layer 145, and the mask layers 109′ by using the patterned mask as a mask. The etching process may be a wet etching process, a dry etching process, or a combination thereof. After the openings 172 are formed, the pattered mask may be removed.

Subsequently, a plurality of capacitor contacts 175 are formed in the openings 172, and a dielectric layer 177 is formed over the dielectric layer 167, as shown in FIG. 25 in accordance with some embodiments. In some embodiments, the capacitor contacts 175 electrically connect the source/drain regions 119b to the subsequently formed capacitors. In some embodiments, the capacitor contacts 175 include a conductive material, such as Cu, W, Al, Ti, Ta, Au, Ag, another suitable conductive material, or a combination thereof.

The capacitor contacts 175 may be formed by a deposition process and a subsequent planarization process. The deposition process may include a CVD process, a PVD process, a sputtering process, a plating process, or another suitable process. The planarization process may be a CMP process. Some materials and processes used to form the dielectric layer 177 are similar to, or the same as those used to form the dielectric layer 161, and details thereof are not repeated herein.

Still referring to FIG. 25, a plurality of openings 180 are formed penetrating through the dielectric layer 177 to expose the capacitor contacts 175, in accordance with some embodiments. The formation of the openings 180 may include forming a patterned mask (not shown) over the dielectric layer 177, and etching the dielectric layer 177 by using the patterned mask as a mask to expose the capacitor contacts 175. The etching process may be a wet etching process, a dry etching process, or a combination thereof. After the openings 180 are formed, the pattered mask may be removed.

Then, referring back to FIGS. 1 and 2, a plurality of capacitors 189 are formed in the openings 180 in the dielectric layer 177, in accordance with some embodiments. As mentioned above, each of the capacitors 189 includes a bottom electrode 183, a top electrode 187, and a dielectric layer 185 sandwiched between the bottom electrode 183 and the top electrode 187. In some embodiments, the capacitors 189 are electrically connected to the source/drain regions 119b through the capacitor contacts 175. The respective step is illustrated as the step S31 in the method 10 shown in FIG. 5.

The formation of the capacitors 189 may include sequentially depositing a conductive material, a dielectric material and another conductive material in the openings 180 (see FIG. 25) and extending over the top surface of the dielectric layer 177, and performing a planarization process (e.g., a CMP process) to remove excess portions of the two conductive materials and the dielectric material.

In some embodiments, the bottom electrodes 183 include TiN or another suitable conductive material. In some embodiments, the dielectric layers 185 include a dielectric material, such as SiO₂, HfO₂, Al₂O₃, ZrO₂, another suitable dielectric material, or a combination thereof. In some embodiments, the top electrodes 187 include TiN, low-stress SiGe, another suitable conductive material, or a combination thereof. After the capacitors 189 are formed, the memory device 100 is obtained. In some embodiments, the memory device 100 is part of a DRAM.

FIGS. 26 and 27 are cross-sectional views illustrating intermediate stages in the formation of the memory device 200, in accordance with some alternative embodiments. It should be pointed out that operations before the structure shown in FIG. 26 are substantially the same as the operations shown in FIGS. 6 to 18, and the related detailed descriptions may refer to the foregoing paragraphs and are not discussed again herein.

After the lining layer 143 is formed, an etching process is performed on the lining layer 143 to expose the mask layers 109′ and the upper gate electrode layers 133′ of the word line structures 141, as shown in FIG. 26 in accordance with some embodiments. In some embodiments, the remaining portions of the lining layer 143 are referred to as lining layers 243′. In some embodiments, the top surfaces TS4 of the upper gate electrode layers 133′ of the word line structures 141 are exposed by the recesses 236.

In some embodiments, the pairs of spacers 131′ of the word line structures 141 are partially exposed by the recesses 236. In some embodiments, the sidewalls USW of the upper portions U of the gate dielectric layers 121′ and the top surfaces TS2 of the gate dielectric layers 121′ are covered by and in direct contact with the lining layers 243′. In some embodiments, the top surfaces TS3 of the lining layers 243′ are higher than the top surfaces TS2 of the gate dielectric layers 121′. In some embodiments, the etching process includes a wet etching process, a dry etching process, or a combination thereof. The respective step is illustrated as the step S25 in the method 10 shown in FIG. 5.

Then, a dielectric cap layer 245 is formed covering the mask layers 109′ and the lining layers 243′, as shown in FIG. 27 in accordance with some embodiments. In some embodiments, the dielectric cap layer 245 has portions extending into the recesses 236 and surrounded by the lining layers 243′. The respective step is illustrated as the step S27 in the method 10 shown in FIG. 5. Some materials and processes used to form the dielectric cap layer 245 are similar to, or the same as those used to form the dielectric cap layer 145, and details thereof are not repeated herein.

After the dielectric cap layer 245 is formed, the following process steps are similar to, or the same as the steps shown in FIGS. 21 to 25, which resulting in the memory device 200 shown in FIGS. 3 and 4, details thereof are not repeated herein.

Embodiments of the memory device 100 and 200 and methods for preparing the same are provided in the disclosure. In some embodiments, both of the memory devices 100 and 200 include the word line structures 141 disposed in the semiconductor substrate 101, and the word line structures 141 include the lower gate electrode layers 123′ and the upper gate electrode layers 133′ with different work functions, and pairs of spacers 131′ disposed on opposite sides of the upper gate electrode layers 133′. Therefore, gate induced drain leakage (GIDL) current can be reduced, which results in an increase of the turn-on speed and an increase of the write speed of the memory devices 100 and 200.

In addition, the air gaps 170 may help to reduce parasitic capacitance and correspondingly improve device performance (e.g., by reducing signal noise). As a result, the performance of the memory devices 100 and 200 can be improved.

In one embodiment of the present disclosure, a memory device is provided. The memory device includes a word line structure disposed in a semiconductor substrate. The word line structure includes a lower gate electrode layer, and an upper gate electrode layer disposed over the lower gate electrode layer. A work function of the lower gate electrode layer is different from a work function of the upper gate electrode layer, and a width of the lower gate electrode layer is greater than a width of the upper gate electrode layer. In addition, the word line structure includes a gate dielectric layer surrounding the lower gate electrode layer and the upper gate electrode layer. The memory device also includes a first source/drain region and a second source/drain region disposed in the semiconductor substrate and at opposite sides of the word line structure. The memory device further includes a bit line structure disposed over and electrically connected to the first source/drain region, and a capacitor disposed over and electrically connected to the second source/drain region.

In another embodiment of the present disclosure, a memory device is provided. The memory device includes a word line structure disposed in a semiconductor substrate. The word line structure includes a lower gate electrode layer, and an upper gate electrode layer disposed over and in direct contact with the lower gate electrode layer. A work function of the lower gate electrode layer is higher than a work function of the upper gate electrode layer. In addition, the word line structure includes a gate dielectric layer surrounding the lower gate electrode layer and the upper gate electrode layer. The memory device also includes a first source/drain region and a second source/drain region disposed in the semiconductor substrate and at opposite sides of the word line structure. The memory device further includes a bit line structure disposed over and electrically connected to the first source/drain region, and a capacitor disposed over and electrically connected to the second source/drain region.

In yet another embodiment of the present disclosure, a method for preparing a memory device is provided. The method includes forming a doped region in a semiconductor substrate, and forming a trench penetrating through the doped region such that a first source/drain region and a second source/drain region are formed at opposite sides of the trench. The method also includes forming a gate dielectric layer and a lower gate electrode layer in the trench. The lower gate electrode layer is surrounded by a lower portion of the gate dielectric layer. The method further includes forming a pair of spacers in the trench and on sidewalls of an upper portion of the gate dielectric layer, and forming an upper gate electrode layer over the lower gate electrode layer and surrounded by the pair of spacers. In addition, the method includes etching the upper gate electrode layer and the pair of spacers to form a recess partially exposing the sidewalls of the upper portion of the gate dielectric layer. The method also includes forming a bit line structure over and electrically connected to the first source/drain region, and forming a capacitor over and electrically connected to the second source/drain region.

The embodiments of the present disclosure have some advantageous features. By forming word line structures having lower and upper gate electrode layers with different work functions and different widths, GIDL current can be reduced, which results in an increase of the turn-on speed and an increase of the write speed of the memory device. As a result, the performance of the memory device can be improved.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, and steps.

What is claimed is:

1. A memory device, comprising:
a word line structure disposed in a semiconductor substrate, wherein the word line structure comprises:
a lower gate electrode layer;
an upper gate electrode layer disposed over the lower gate electrode layer, wherein a work function of the lower gate electrode layer is different from a work function of the upper gate electrode layer;
a pair of spacers disposed on opposite sides of the upper gate electrode layer; and
a gate dielectric layer surrounding the lower gate electrode layer and the pair of spacers;
a first source/drain region and a second source/drain region disposed in the semiconductor substrate and at opposite sides of the word line structure;
a bit line structure disposed over and electrically connected to the first source/drain region; and
a capacitor disposed over and electrically connected to the second source/drain region.

2. The memory device of claim 1, wherein the work function of the lower gate electrode layer is higher than the work function of the upper gate electrode layer.

3. The memory device of claim 1, wherein the lower gate electrode layer comprises titanium nitride (TiN), and the upper gate electrode layer comprises polysilicon.

4. The memory device of claim 1, wherein the lower gate electrode layer is in direct contact with the upper gate electrode layer.

5. The memory device of claim 1, wherein the gate dielectric layer has a lower portion surrounding the lower gate electrode layer and an upper portion, and a thickness of the lower portion of the gate dielectric layer is greater than a thickness of the upper portion of the gate dielectric layer.

6. The memory device of claim 1, wherein the upper gate electrode layer is separated from the gate dielectric layer by the pair of spacers.

7. The memory device of claim 1, wherein the lower gate electrode layer is in direct contact with the pair of spacers.

8. The memory device of claim 1, further comprising:
a dielectric cap layer disposed over the semiconductor substrate, wherein a portion of the dielectric cap layer extends into the semiconductor substrate to cover the word line structure.

9. The memory device of claim 8, wherein the dielectric cap layer is in direct contact with the upper gate electrode layer.

10. The memory device of claim 9, wherein the dielectric cap layer is in direct contact with the pair of spacers.

11. The memory device of claim 8, further comprising:
a lining layer disposed between the gate dielectric layer and the dielectric cap layer.

12. The memory device of claim 11, wherein the lining layer is in direct contact with the pair of spacers.

13. The memory device of claim 11, wherein the upper gate electrode layer and the pair of spacers are separated from the dielectric cap layer by the lining layer.

14. The memory device of claim 11, wherein the lining layer extends over the semiconductor substrate, and a top surface of the gate dielectric layer is covered by the lining layer.

15. The memory device of claim 11, further comprising:
a bit line contact disposed between the first source/drain region and the bit line structure, wherein the bit line contact is in direct contact with the lining layer.

16. The memory device of claim 11, further comprising:
a mask layer disposed between the capacitor and the second source/drain region of the semiconductor substrate, wherein the mask layer is in direct contact with the lining layer.

17. The memory device of claim 16, further comprising:
a capacitor contact disposed between and electrically connect the capacitor and the second source/drain region of the semiconductor substrate, wherein the capacitor contact penetrates through the mask layer.
